(19) United States
(12) Patent Application Publication
(10) Pub. No.: US 2023/0389297 A1
(43) Pub. Date: Nov. 30, 2023

(54) SEMICONDUCTOR STRUCTURE AND METHOD FOR FORMING THE SAME

(71) Applicant: Winbond Electronics Corp., Taichung City (TW)

(72) Inventor: Chieh-Chun YU, Taichung City (TW)

(21) Appl. No.: 17/829,015

(22) Filed: May 31, 2022

(51) Int. Cl. H01L 27/108; H01L 23/528; H01L 23/532

(52) U.S. Cl. CPC H01L 27/10885; H01L 27/10888; H01L 27/10876; H01L 27/10823; H01L 23/5283; H01L 23/53295

(57) ABSTRACT

A method for forming a semiconductor structure is provided. The method includes providing a substrate. The method further includes forming contact openings on the substrate, with sidewalls of the contact openings disposed with a dielectric liner. The method further includes forming a bit line structure on the substrate, wherein the bit line structure spans the contact openings in a first direction. The dielectric liner surrounds the bit line structure within the contact openings, and the dielectric liner extends into the bit line structure above a top surface of the substrate.

### BACKGROUND

### Technical Field

The present disclosure relates to a semiconductor structure and a method for forming the same, and in particular it relates to a semiconductor structure including a dielectric liner and a method for forming the same.

### Description of the Related Art

Dynamic Random Access Memory (DRAM) is widely used in consumer electronic products. In order to increase the device density in a dynamic random access memory and improve its overall performance, the technology used in its manufacturing is currently trending towards miniaturization of the device size.

However, as device dimensions shrink, many challenges arise. For example, when forming the active region of a memory device, due to the different deposition rates of materials of the active region on surfaces of different compositions, the portion with a faster deposition rate will be sealed early, and a seam will be generated in the active region. The above-mentioned seam may be rounded due to recrystallization in a subsequent thermal process and form voids with circular cross-sections, resulting in an increase in the resistance of the subsequently formed bit line structure.

### BRIEF SUMMARY

The present disclosure provides a method for forming a semiconductor structure. The method includes providing a substrate. The method further includes forming contact openings on the substrate, with sidewalls of the contact openings disposed with a dielectric liner. The method further includes forming a bit line structure on the substrate, wherein the bit line structure spans the contact openings in a first direction. The dielectric liner surrounds the bit line structure within the contact openings, and the dielectric liner extends into the bit line structure above a top surface of the substrate.

The present disclosure provides a semiconductor structure which includes a substrate, a dielectric liner, and a bit line structure. The substrate has contact openings. The dielectric liner is disposed on sidewalls of the contact openings. The bit line structure is disposed over the substrate and spans the contact openings in a first direction. The dielectric liner surrounds the bit line structure within the contact openings, and the dielectric liner extends into the bit line structure above a top surface of the substrate.

### BRIEF DESCRIPTION OF THE DRAWINGS

FIGS. 1A, 2-7, 8A, 9 and 10A illustrate cross-sectional views of various stages in a manufacturing process of a semiconductor structure, in accordance with some embodiments of the present disclosure.

FIG. 1B illustrates a top view of the semiconductor structure corresponding to FIG. 1A, in accordance with some embodiments of the present disclosure.

FIG. 8B illustrates a top view of the semiconductor structure corresponding to FIG. 8A, in accordance with some embodiments of the present disclosure.

FIG. 10B illustrates a top view of the semiconductor structure corresponding to FIG. 10A, in accordance with some embodiments of the present disclosure.

### DETAILED DESCRIPTION

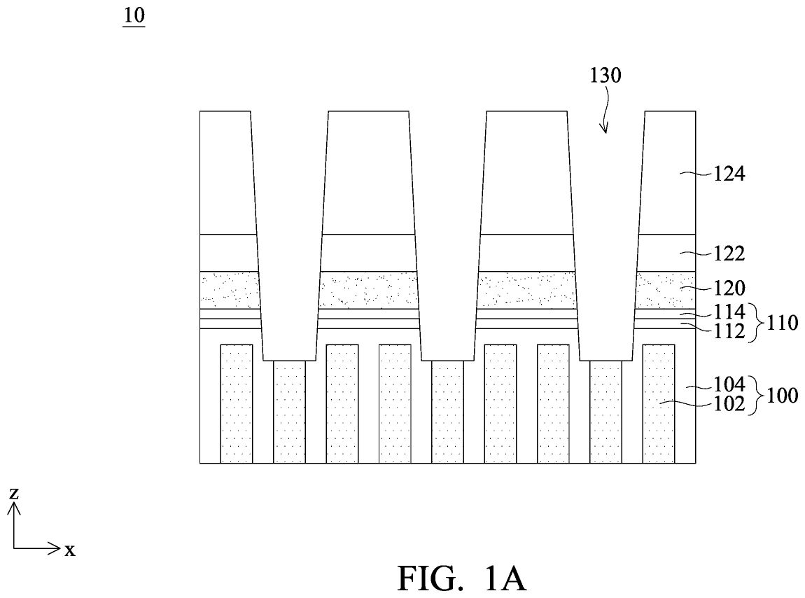

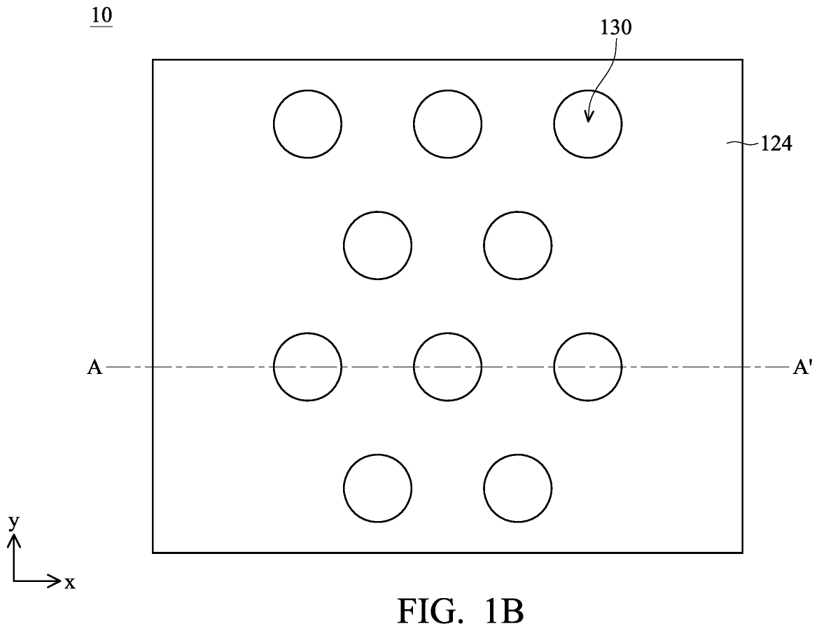

FIG. 1A shows a cross-sectional view of an intermediate stage of the fabrication process of a semiconductor structure 10. In some embodiments, the semiconductor structure 10 is part of a dynamic random access memory array. However, it should be understood that those skilled in the art may also apply the structures and formation methods of the present disclosure to other types of memory devices.

First, a substrate 100 is provided. The substrate 100 may be an elemental semiconductor substrate, such as a silicon substrate, or a germanium substrate; or a compound semiconductor substrate, such as a silicon carbide substrate, or a gallium arsenide substrate. In some embodiments, the substrate 100 may be a semiconductor-on-insulator (SOI) substrate.

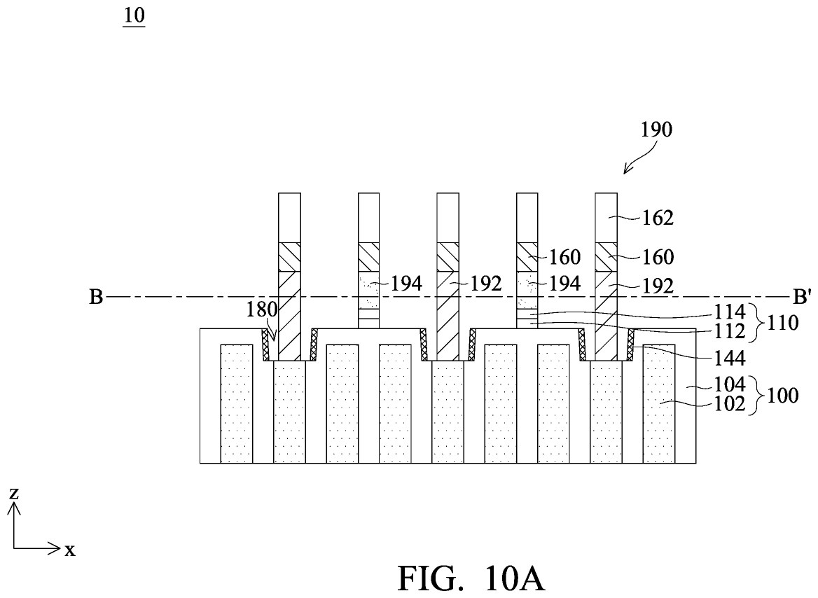

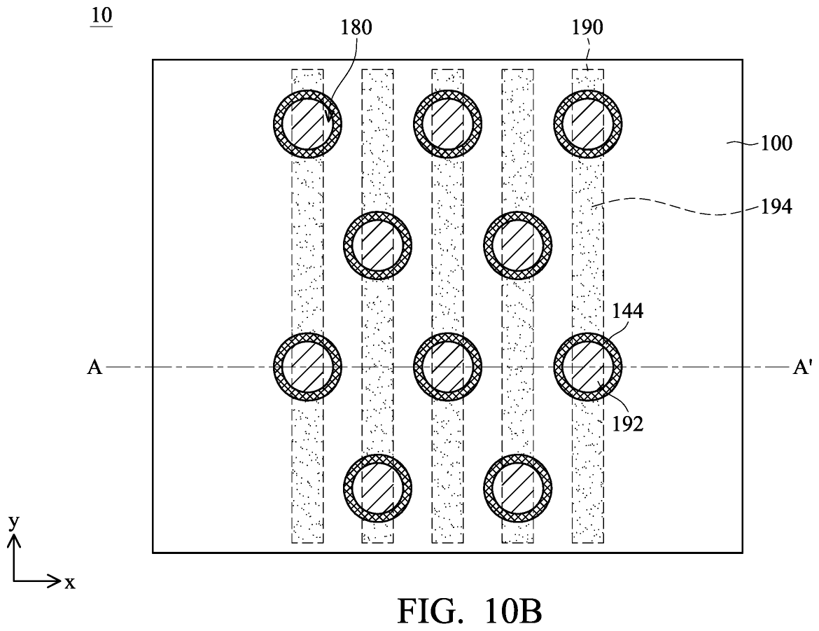

In some embodiments, isolating features are formed on the conductive substrate 100, a conductive portion 102 and an isolation portion 104 may be formed on the substrate 100. The conductive portion 102 may electrically connect with a subsequently formed bit line structure (e.g., the bit line structure 190 in FIG. 10A), and the isolation portion 104 may be alternately arranged with the conductive portion 102. Although the conductive portion 102 is shown as not being exposed on the topmost surface of the substrate 100 in FIG. 1A, in other examples, the conductive portion 102 may be exposed on the topmost surface of the substrate 100.

In some embodiments, the conductive portion 102 includes a conductive material such as silicon, germanium, silicon carbide, gallium arsenide, other suitable materials, or a combination thereof. In some embodiments, the isolation portion 104 includes a nitride or an oxide, such as silicon oxide, silicon nitride, silicon oxynitride, other suitable materials, or a combination thereof. In some embodiments, the isolation portion 104 is a shallow trench isolation (STI) structure of the substrate 100. The isolation portion 104 may be formed through a deposition process (such as chemical vapor deposition (CVD)), a patterning process (such as a lithography process and an etching process), a planarization process (such as chemical mechanical polishing, CMP), or any suitable process.

Next, a capping layer 110 may be formed on the substrate 100 to protect the elements in the substrate 100 from being damaged by subsequent processes. In some embodiments, the capping layer 110 includes a nitride layer 112 and an oxide layer 114. The nitride layer 112 includes, for example, silicon nitride or silicon oxynitride. The oxide layer 114 includes, for example, a silicon oxide layer formed of tetraethylorthosilicate (TEOS). The method of forming the nitride layer 112 and the oxide layer 114 may be a physical vapor deposition (PVD) process, a CVD process, an atomic layer deposition (ALD) process, or any suitable deposition processes. In one embodiment, the method for forming the oxide layer 114 is In-Situ Steam Generation (ISSG).

Next, a semiconductor material 120 may be formed over the substrate 100. In some embodiments, the semiconductor material 120 is separated from the substrate 100. For example, the capping layer 110 may separate the semiconductor material 120 from the substrate 100. In some embodiments, the semiconductor material 120 includes, for example, polysilicon.

Next, an oxide layer 122 and a mask layer 124 are formed on the semiconductor material 120 in sequence. In some embodiments, the oxide layer 122 is used as a barrier layer for subsequent etch back of conductive materials (such as the conductive material 150). The oxide layer 122 may include, for example, tetraethoxysilane (TEOS), and the mask layer 124 may include any suitable mask material, such as a photoresist. The formation of the mask layer 124 may include forming a mask material on the oxide layer 122, and then performing a patterning process on the mask material to form the patterned mask layer 124. In some embodiments, the pattern of the mask layer 124 is determined according to the cross-sectional shape of the openings to be formed subsequently (for example, the first openings 130 shown in FIGS. 1A and 1B), and the pattern of the mask layer 124 is substantially corresponded to the shapes of the subsequently formed contact openings (see the contact openings 180 in FIG. 10B).

Continuing to refer to FIG. 1A, an etching process may be performed to form first openings 130 through the semiconductor material 120 on the substrate 100, and the shapes and positions of the first openings 130 may be aligned with the pattern of the mask layer 124. The above-mentioned etching process may include, for example, a dry etching process or a wet etching process. The first openings 130 may extend into a portion of the substrate 100, and the conductive portion 102 in the substrate 100 may be exposed in the first openings 130.

FIG. 1B illustrates a top view of the semiconductor structure 10 corresponding to FIG. 1A, wherein FIG. 1A corresponds to the section AA′ in FIG. 1B. As shown in FIG. 1B, the positions of the first openings 130 may form an array in the semiconductor structure 10, and each of the first openings 130 defines the position of the active region of the semiconductor structure 10. It should be noted that although each of the first openings 130 is illustrated as having a circular cross-section in FIG. 1B, the present disclosure does not specifically limit the cross-sectional shapes of the first openings 130. For example, each of the first openings 130 may also have a shape that is rectangular, polygonal, oval, irregular, or another suitable cross-sectional shape.

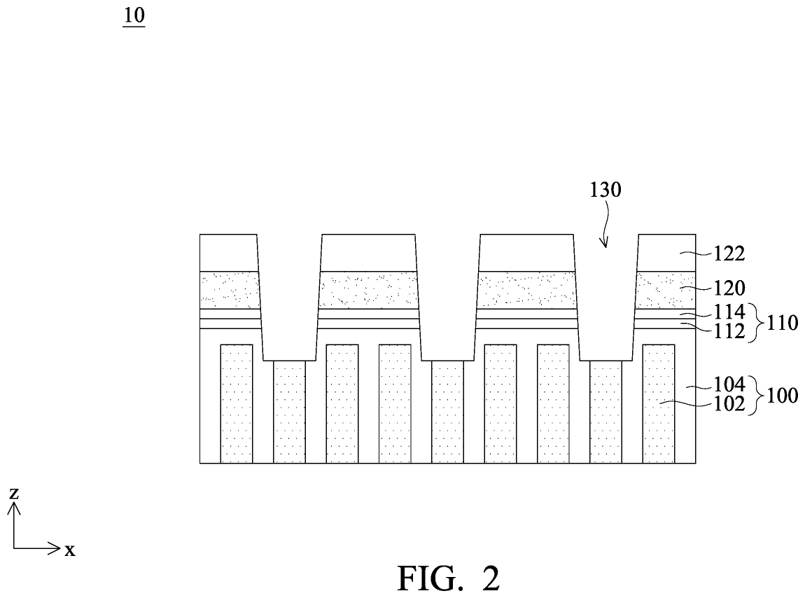

As shown in FIG. 2, after the first opening 130 is formed, the mask layer 124 may be removed to expose the top surface of the oxide layer 122. Methods for removing the mask layer 124 may include, for example, an etching process or an ashing process. In one embodiment, an ashing process may be used to remove the mask layer 124 including organic components.

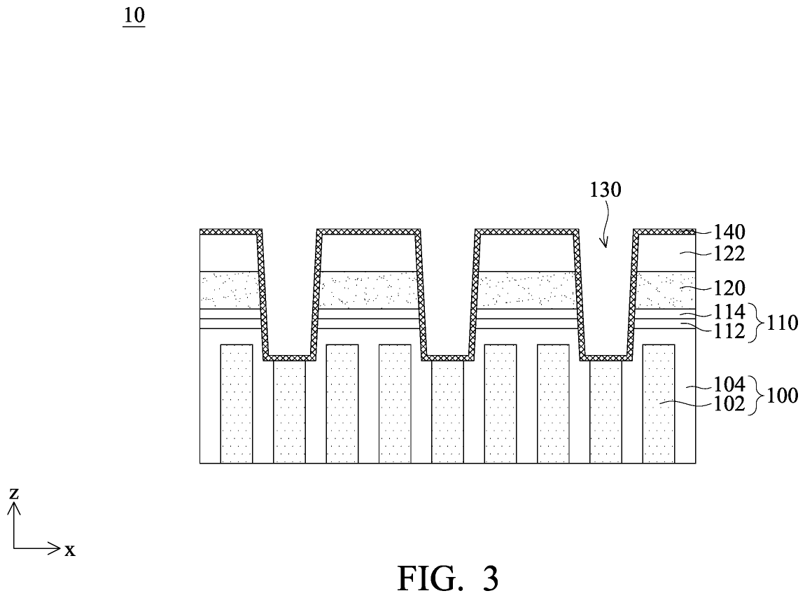

Referring to FIG. 3, a dielectric material 140 may be conformally deposited within the first openings 130, and the dielectric material 140 may extend along the top surface of the oxide layer 122, the sidewalls of the first openings 130, and the bottom of the first opening 130. In some embodiments, the sidewalls of the first openings 130 include the sidewalls of the capping layer 110, the semiconductor material 120, and the oxide layer 122. The dielectric material 140 may include a nitride such as silicon nitride, or another material that will not be etched away easily in subsequent processes. For example, the dielectric material 140 may be a material having an etch selectivity to that of the oxide layer 122 so as not to be easily removed in the subsequent process of etching the oxide layer 122. The method of forming the dielectric material 140 may include PVD, CVD, ALD, another suitable method, or a combination thereof.

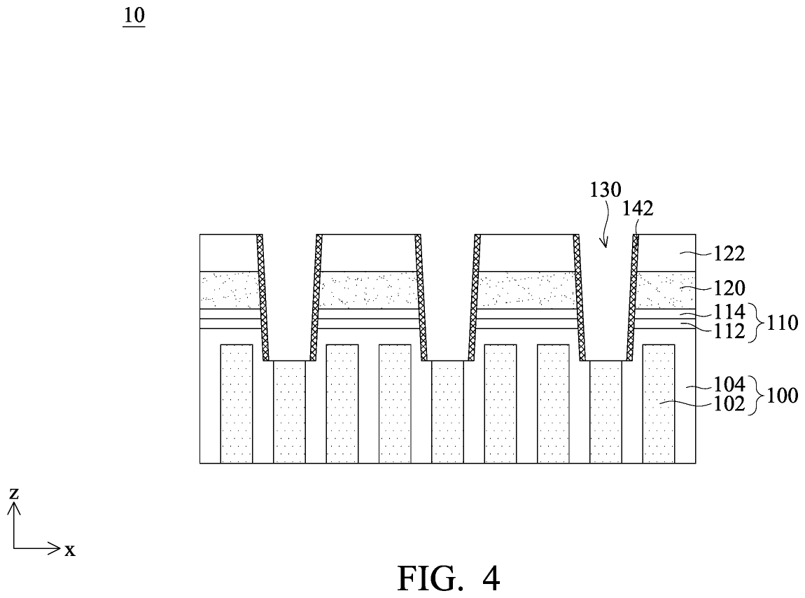

Referring to FIG. 4, after the dielectric material 140 is deposited, an anisotropic etching process may be performed to remove the dielectric material 140 at the bottom of the first openings 130. As such, a dielectric spacer layer 142 may be formed on the sidewalls of the first openings 130 (including the sidewalls of the semiconductor material 120) to expose the substrate 100. By exposing the substrate 100, especially the conductive portion 102 of the substrate 100, in the first openings 130, the subsequently formed bit line structure can be electrically connected to the substrate 100 at the active region of the semiconductor structure 10. In some embodiments, portions of the dielectric material 140 overlying oxide layer 122 are also removed by the anisotropic etching process. In some embodiments, the above-mentioned anisotropic etching process includes a dry etching process, such as a reactive ion etching (RIE) process.

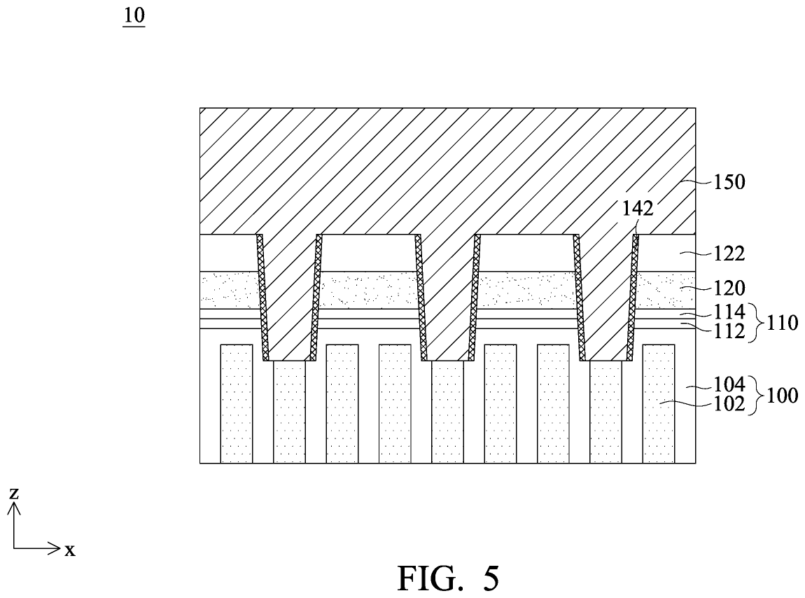

Referring to FIG. 5, after the dielectric spacer layer 142 is formed, a conductive material 150 may be formed over the substrate 100 and in the first openings 130, and the semiconductor material 120 and the conductive material 150 are separated by the dielectric spacer layer 142. By forming the dielectric spacer layer 142 on the sidewalls of the first openings 130, the conductive material 150 may have a uniform deposition rate in the first openings 130. Compared with the embodiments of the present disclosure, if the first openings 130 are filled by the conductive material 150 directly, without the dielectric spacer layer 142, a conductive material having seams therein may be formed.

For example, in embodiments in which the conductive material 150 includes doped polysilicon and that the substrate 100 and the semiconductor material 120 include polysilicon, the conductive material 150 has a higher deposition rate on the sidewalls of the substrate 100 and the semiconductor material 120 than on the capping layer 110 or the oxide layer. The portion with the higher deposition rate will seal early and form seams inside the conductive material 150. The above-mentioned seams may be rounded due to recrystallization and form voids with circular cross-sections, resulting in an increase in the resistance of the subsequently formed bit line structure.

In some embodiments, the conductive material 150 includes doped polysilicon, metals, metal nitrides, other suitable conductive materials, or a combination thereof. The formation of the conductive material 150 includes filling the conductive material 150 in the first openings 130, and the formation method may include, for example, a PVD process, a CVD process, an ALD process, e-beam evaporation, electroplating, or any suitable deposition process. In some embodiments, excess conductive material 150 is formed over the first openings 130 and the oxide layer 122.

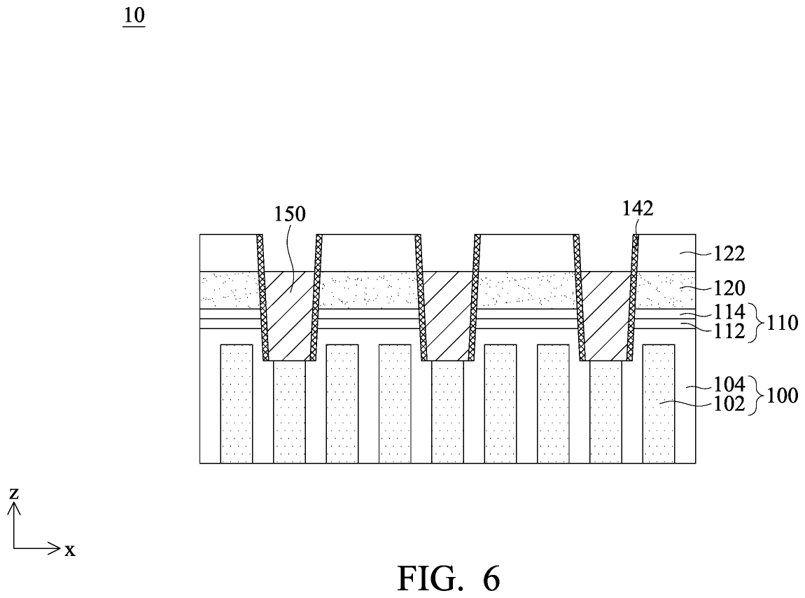

Referring to FIG. 6, after the conductive material 150 is formed, a suitable planarization process and an etch back process may be performed to remove excess conductive material 150 over the top surface of the oxide layer 122. In some embodiments, portions of the conductive material 150 between the sidewalls of oxide layer 122 are also removed, and the dielectric spacer layer 142 remains on the sidewalls of oxide layer 122. In some embodiments, the conductive material 150 is etched back to be substantially level with the top surface of the semiconductor material 120.

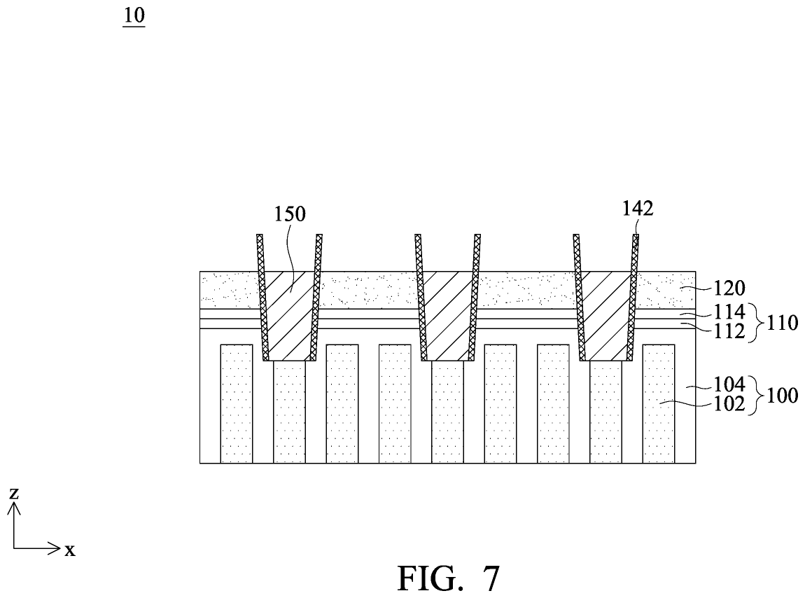

Referring to FIG. 7, the oxide layer 122 is removed, leaving the portion of the dielectric spacer layer 142 that is protruding from the top surfaces of the conductive material 150 and the semiconductor material 120. The above-mentioned removal process may include, for example, a dry etching or wet etching process. In some embodiments, the above-mentioned removal is performed by a wet etching process, and the used etchant includes hydrofluoric acid (HF), nitric acid (HNO₃), sulfuric acid (H₂SO₄), phosphoric acid (H₃PO₄), hydrochloric acid (HCl), ammonia (NH₃), other suitable etchants, or a combination thereof. In one embodiment, the oxide layer 122 including TEOS may be etched using an etchant including dilute HF (DHF) to remove the oxide layer 122.

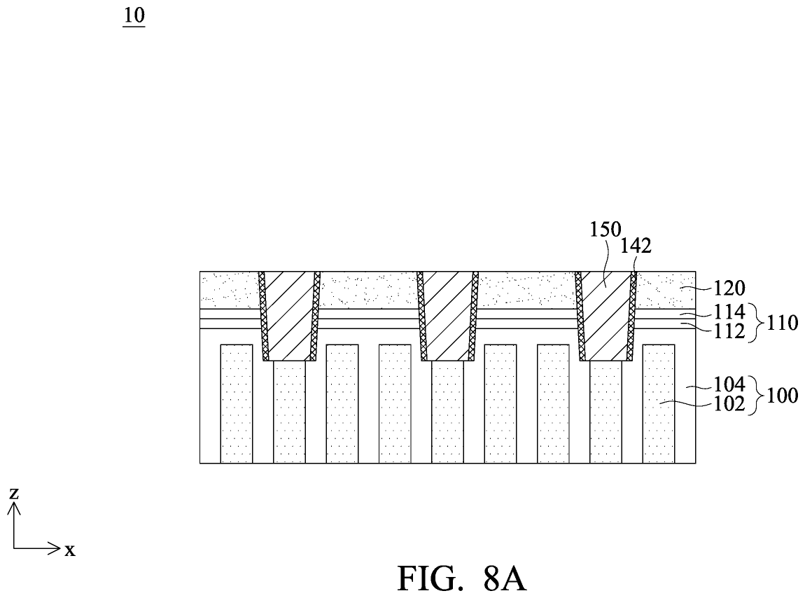

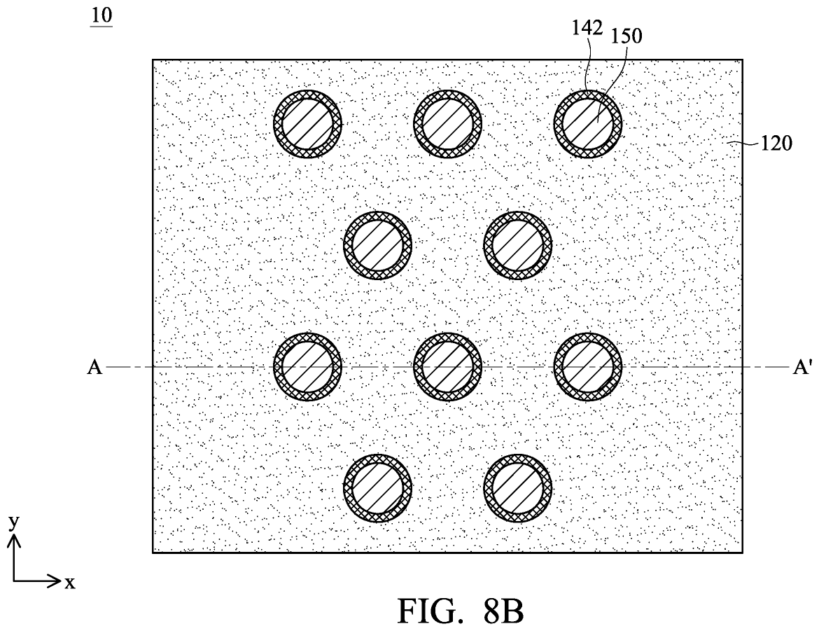

Referring to FIG. 8A, the protruding portions of the dielectric spacer layer 142 above the top surfaces of the conductive material 150 and the semiconductor material 120 are removed. The top surface of the dielectric spacer layer 142 after the removal process is substantially coplanar with the top surfaces of the conductive material 150 and the semiconductor material 120. The above-mentioned removal process may include, for example, a dry etching or wet etching process. In some embodiments, the above-mentioned removal is performed by a wet etching process, and the used etchants include hydrofluoric acid (HF), nitric acid (HNO₃), sulfuric acid (H₂SO₄), phosphoric acid (H₃PO₄), hydrochloric acid (HCl), Ammonia (NH₃), other suitable etchants, or a combination thereof. In one embodiment, the dielectric spacer layer 142 including silicon nitride may be etched by using an etchant including phosphoric acid to remove the portions of the dielectric spacer layer 142 protruding from the top surfaces of the conductive material 150 and the semiconductor material 120.

FIG. 8B illustrates a top view of the semiconductor structure 10 corresponding to FIG. 8A, wherein FIG. 8A corresponds to the section AA′ in FIG. 8B. As shown in FIG. 8B, the positions of the dielectric spacer layer 142 and the conductive material 150 may form an array in a top view of the semiconductor structure 10 perpendicular to the z-direction, and the dielectric spacer layer 142 defines the active region of the semiconductor structure 10.

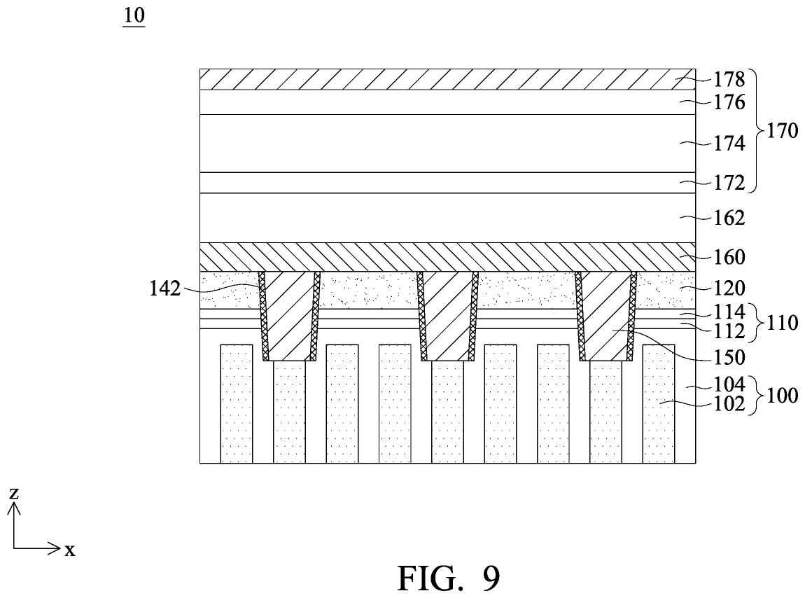

Next, referring to FIG. 9, an adhesive layer 160, a silicon nitride layer 162, and a hard mask layer 170 are sequentially formed on the semiconductor material 120, the dielectric spacer layer 142 and the conductive material 150. In some embodiments, the hard mask layer 170 includes a silicon oxide layer 172, a carbon layer 174, a silicon oxynitride layer 176 and a polysilicon layer 178. The adhesive layer 160 can reduce the resistance of the subsequently formed bit line structure, the silicon nitride layer 162 can be used as a hard mask for the gate contacts of the peripheral circuit region (not shown) of the semiconductor structure 10, and each of the layers in the hard mask layer 170 may be patterned or used as an etch mask in multiple patterning processes.

The material of the adhesive layer 160 may include titanium, titanium nitride, other suitable materials, or a combination thereof. The method of forming the adhesion layer 160 may include PVD, CVD, ALD, e-beam evaporation, electroplating, another suitable method, or a combination thereof. The formation method of the silicon nitride layer 162 may include PVD, CVD, ALD, another suitable method, or a combination thereof.

FIGS. 10A and 10B illustrate a cross-sectional view and a top view of the semiconductor structure 10, respectively. It should be noted that FIG. 10A is a cross-sectional view corresponding to section AA′ in FIG. 10B, and FIG. 10B is a top view corresponding to section BB′ in FIG. 10A. As shown in FIGS. 10A and 10B, various etching processes may be performed to form contact openings 180 exposing the substrate 100 and a bit line structure 190 over the substrate 100, and the bit line structure 190 spans multiple contact openings 180 in the y-direction. For clarity, the location of the bit line structure 190 is shown in dashed lines in FIG. 10B. In addition, the portion of the dielectric spacer layer 142 that does not intersect the bit line structure 190 and is higher than the substrate 100 is also removed in the above etching process, thereby forming a dielectric liner 144 disposed on the sidewalls of the contact openings 180. In some embodiments, the dielectric liner 144 surrounds the bit line structure 190 within the contact openings 180, and the portion of the dielectric liner 144 that intersects the bit line structure 190 (see FIG. 10B) extends into the bit line structure 190 (not shown) above the top surface of the substrate.

The conductive material 150 and the semiconductor material 120 may be etched in the above-described etching process to form the bit line structure 190 over the substrate 100, and the conductive material 150 and the semiconductor material 120 are respectively etched to form a contact 192 and a semiconductor layer 194 of the bit line structure 190. As shown in FIG. 10A, the contact 192 may be disposed directly above the contact openings 180, and the semiconductor layer 194 may be disposed above the substrate 100 (including the portions directly above the substrate 100 and without the contact opening 180). Referring to FIG. 10B, the semiconductor layer 194 and the contact 192 are separated by a portion of the dielectric liner 144, wherein the above portion is the portion where the dielectric liner 144 and the bit line structure 190 intersect, and the bit line structure 190 is in physical contact with the dielectric liner 144 in the y-direction.

In some embodiments, the bit line structure 190 further includes an adhesive layer 160 and a silicon nitride layer 162 over the contact 192 and the semiconductor layer 194. The contact 192 may be connected to the substrate 100 at the bottom surface of the contact opening 180, and particularly, to be electrically connected to the conductive portion 102. In some embodiments, the bit line structure 190 further includes the capping layer 110 under the semiconductor layer 194, and the substrate 100 and the semiconductor layer 194 are separated from each other.

Continue to refer to FIGS. 10A and 10B. In some embodiments, the dielectric liner 144 completely covers the sidewalls of the contact openings 180. In some embodiments, the portions of the dielectric liner 144 that intersects the bit line structure 190 are level with the top surface of the contact 192. In some embodiments, the portion of the dielectric liner 144 that does not intersect the bit line structure 190 is level with the top surface of the substrate 100. In some embodiments, there is a spacing in the x-direction between the bit line structure 190 and the dielectric liner 144 in the contact openings 180.

In summary, the present disclosure provides a semiconductor structure and a method of forming the same, wherein a dielectric spacer layer is formed over the semiconductor structure prior to depositing a conductive material for an active region of a memory device. By forming a dielectric spacer layer to cover the surfaces of the structure around the active region, the conductive material can be grown on these surfaces at a uniform rate, preventing defects such as seams from forming in the active region. In this way, it is possible to avoid generation of voids in the subsequently formed bit line structure, reduce the resistance of the bit line structure, and improve the yield of the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
providing a substrate;
forming contact openings on the substrate, with a dielectric liner disposed on sidewalls of the contact openings; and
forming a bit line structure over the substrate, wherein the bit line structure spans the contact openings in a first direction,
wherein the dielectric liner surrounds the bit line structure within the contact openings, and the dielectric liner extends into the bit line structure above a top surface of the substrate.

2. The method for forming a semiconductor structure as claimed in claim 1, further comprising:
forming a semiconductor material above the substrate;
forming a dielectric spacer layer on sidewalls of the semiconductor material; and
forming a conductive material over the substrate, wherein the semiconductor material and the conductive material are separated by the dielectric spacer layer.

3. The method for forming a semiconductor structure as claimed in claim 2, further comprising etching the conductive material and the semiconductor material to form a contact and a semiconductor layer of the bit line structure, respectively.

4. The method for forming a semiconductor structure as claimed in claim 2, further comprising removing a portion of the dielectric spacer layer higher than top surfaces of the conductive material and the semiconductor material.

5. The method for forming a semiconductor structure as claimed in claim 2, further comprising:
forming first openings through the semiconductor material over the substrate; and
forming the dielectric spacer layer on sidewalls of the first openings,
wherein the conductive material is filled into the first openings.

6. The method for forming a semiconductor structure as claimed in claim 5, wherein forming the dielectric spacer layer comprises:
conformally depositing a dielectric material within the first openings; and
removing a portion of the dielectric material to expose the substrate at the bottom of the first openings.

7. The method for forming a semiconductor structure as claimed in claim 5, further comprising:
removing a portion of the dielectric spacer layer that does not intersect the bit line structure and is higher than the substrate to form the dielectric liner.

8. The method for forming a semiconductor structure as claimed in claim 1, further comprising performing an etching process to form the contact openings, and the contact openings expose the substrate.

9. A semiconductor structure, comprising:
a substrate having contact openings;
a dielectric liner disposed on sidewalls of the contact openings; and
a bit line structure disposed over the substrate and spanning the contact openings in a first direction,
wherein the dielectric liner surrounds the bit line structure within the contact openings, and the dielectric liner extends into the bit line structure above a top surface of the substrate.

10. The semiconductor structure as claimed in claim 9, wherein the dielectric liner completely covers the sidewalls of the contact openings.

11. The semiconductor structure as claimed in claim 9, wherein the bit line structure comprises:
a contact disposed directly above the contact openings; and
a semiconductor layer disposed above the substrate, and the contacts are separated by the dielectric liner.

12. The semiconductor structure as claimed in claim 11, wherein the contact is electrically connected to the substrate at a bottom surface of the contact openings.

13. The semiconductor structure as claimed in claim 11, wherein a portion of the dielectric liner that intersects the bit line structure is level with a top surface of the contact.

14. The semiconductor structure as claimed in claim 9, wherein a portion of the dielectric liner that does not intersect the bit line structure is level with the top surface of the substrate.

15. The semiconductor structure as claimed in claim 9, wherein the bit line structure is in physical contact with the dielectric liner in the first direction.

16. The semiconductor structure as claimed in claim 9, wherein there is a spacing between the bit line structure and the dielectric liner in a second direction, and the second direction is perpendicular to the first direction.

17. The semiconductor structure as claimed in claim 9, wherein the dielectric liner comprises silicon nitride.

18. The semiconductor structure as claimed in claim 9, wherein the substrate and the semiconductor layer are separated from each other.

19. The semiconductor structure as claimed in claim 9, wherein the substrate comprises:
a conductive portion electrically connected to the bit line structure; and
an isolation portion alternately arranged with the conductive portion, wherein the dielectric liner is disposed over the isolation portion.

20. The semiconductor structure as claimed in claim 19, wherein the conductive portion comprises silicon, and the isolation portion comprises silicon oxide.
